(19) United States
(12) Patent Application Publication
(10) Pub. No.: US 2010/0012187 A1
(43) Pub. Date: Jan. 21, 2010

(54) ENCAPSULATION OF A PHOTOVOLTAIC CONCENTRATOR

(75) Inventors: James B. Paull, Andover, MA (US); Peter Morse, Essex, MA (US)

Correspondence Address: GROSSMAN, TUCKER, PERREAULT & PFLEGER, PLLC, 55 SOUTH COMMERICAL STREET, MANCHESTER, NH, 03101, US

(73) Assignee: STELLARIS CORPORATION, North Billerica, MA (US)

(21) Appl. No.: 12/504,647

(22) Filed: Jul. 16, 2009

Related U.S. Application Data
(60) Provisional application No. 61/081,970, filed on Jul. 18, 2008.

(51) Int. Cl. H01L 31/00

(52) U.S. Cl. 136/259

(57) ABSTRACT

Techniques are disclosed for protecting a photovoltaic device from the environment. An electrical interconnection is also provided for increased mechanical and electrical protection of the photovoltaic and electrical interconnections between lens cell assemblies configured in an array using an enclosed busway structure. Also provided is a method of leading the electrical contacts from the photovoltaic material within the lens cell assembly such that there is a positive seal provided by the lens encapsulating material. One such embodiment comprises a passage within the lens itself, which serves as a conduit for electrical leads from the photovoltaic material. The internal passage for electrical leads enables the ability to completely wrap and seal the lens assembly with encapsulating film, which in combination with an enclosed busway operatively coupling an array of lens assemblies, allows for a highly manufacturable and secure seal over the photovoltaic system.

### RELATED APPLICATIONS

This application claims the benefit of U.S. Provisional Application No. 61/081,970, filed Jul. 18, 2008. In addition, this application is related to U.S. patent application Ser. No. 11/773,866, filed Jul. 5, 2007, and titled “Apparatus and Method for Forming a Photovoltaic Device.” Each of these applications is herein incorporated by reference in its entirety.

### FIELD OF THE INVENTION

The invention relates to photovoltaic devices, and more particularly, to encapsulation and electrical connection techniques and structures for photovoltaic devices and assemblies.

### BACKGROUND OF THE INVENTION

U.S. Patent Application Publication No. 2008/0053515 discloses techniques for encapsulating a photovoltaic device. Specifically, the techniques provide an effective way to join photovoltaic material together with a light concentrating lens in such a way that ensures high optical efficiency for generation of photovoltaic electricity, protection from environmental hazards such as water vapor penetration, electrical insulation and allowance for differential expansion of materials in the assembly. Also disclosed are approaches for making electrical connections from a lens cell assembly to draw away the electricity produced by the photovoltaic material.

One consideration related to the integrity of the encapsulation is ensuring that a continuous seal is maintained around material interfaces, particularly at the ends of the lens cell assemblies where there is a complex three dimensional geometry that must accommodate a positive seal around the electrical leads from the photovoltaic material within the lens assembly.

### SUMMARY OF THE INVENTION

One embodiment of the present invention provides a photovoltaic assembly. The assembly includes a concentrating lens having a passage therein for electrical leads, and a photovoltaic material at a target of the concentrating lens and operatively coupled to the electrical leads. The assembly further includes a film that encapsulates (partially or completely) the assembly without any break in the film to accommodate the electrical leads. In one particular case, the assembly further includes a backing strip to the photovoltaic material. In one such case, the backing strip has a convex outer shape that the film wraps around. In another such case, the concentrating lens has a lower portion where the photovoltaic material is located and a raised portion at one end of the lower portion, the raised end approximating a shape of the photovoltaic material and backing strip. In another particular, the assembly is used in an array including a plurality of assemblies. In one such case, the electrical leads of each assembly are electrically connected to respective bus bars. In another particular case, an opening of the passage in the concentrating lens mates to an opening in a structural member coupled to the concentrating lens. In one such case, the opening provides access to an enclosed busway that houses negative and positive bus bars to which the electrical leads can be operatively coupled. The film can be, for example, a clear film or an opaque film with a reflective surface on the concentrating lens side.

A number of variations will be apparent in light of this disclosure. For instance, another example embodiment provides a photovoltaic assembly that includes a concentrating lens having a passage therein for electrical leads, wherein an opening of the passage mates to an opening in a structural member coupled to the concentrating lens. The assembly further includes a photovoltaic material at a target of the concentrating lens and operatively coupled to the electrical leads, and a film that encapsulates the assembly without any break in the film to accommodate the electrical leads. The film can be, for instance, a clear film or an opaque film with a reflective surface on its lens side. The assembly further includes a backing strip to the photovoltaic material, wherein the backing strip has a convex outer shape that the film wraps around. In one particular case, the concentrating lens has a lower portion where the photovoltaic material is located and a raised portion at one end of the lower portion, the raised end approximating a shape of the photovoltaic material and backing strip. In another particular case, the assembly is used in an array including a plurality of assemblies. In one such case, the electrical leads of each assembly are electrically connected to respective bus bars. In another particular case, the opening leads to an enclosed busway that houses negative and positive bus bars to which the electrical leads can be operatively coupled. Just as with the previous embodiment, note that the passage allows the electrical leads to be effectively completely internal to the assembly, thereby never impeding the film, whether partially or completely encapsulating the assembly.

Another variation of a photovoltaic assembly configured in accordance with an embodiment of the present invention includes a concentrating lens having a passage therein for electrical leads, wherein an opening of the passage mates to an opening in a structural member coupled to the concentrating lens, and the opening leads to an enclosed busway that houses negative and positive bus bars to which the electrical leads can be operatively coupled. The assembly further includes a photovoltaic material at a target of the concentrating lens and operatively coupled to the electrical leads, and a film that encapsulates the assembly without any break in the film to accommodate the electrical leads, wherein the film is one of a clear film or an opaque film with a reflective surface on the concentrating lens side. The assembly is used in an array including a plurality of assemblies, and the electrical leads of each assembly are electrically connected to respective bus bars. In one particular case, a backing strip to the photovoltaic material, wherein the backing strip has a convex outer shape that the film wraps around. In another particular case, the concentrating lens has a lower portion where the photovoltaic material is located and a raised portion at one end of the lower portion, the raised end approximating a shape of the photovoltaic material and backing strip. Again, note that the passage allows the electrical leads to be effectively completely internal to the assembly, thereby never interfering with the film, whether partially or completely encapsulating the assembly.

The features and advantages described herein are not all-inclusive and, in particular, many additional features and advantages will be apparent to one of ordinary skill in the art in view of the drawings, specification, and claims. Moreover, it should be noted that the language used in the specification has been principally selected for readability and instructional purposes, and not to limit the scope of the inventive subject matter.

### BRIEF DESCRIPTION OF THE DRAWINGS

FIG. 1 is an orthogonal view of an end of a lens cell assembly incorporating mono-facial photovoltaic material, in accordance with an embodiment of the present invention.

FIG. 2 is a section through a part of a lens cell assembly incorporating mono-facial photovoltaic material as it is attached to a support member and busway, in accordance with an embodiment of the present invention.

FIG. 3 is an orthogonal view of an end of a lens cell assembly incorporating mono-facial photovoltaic material but without a backing strip, in accordance with an embodiment of the present invention.

FIG. 4 is an orthogonal view of an end of a lens cell assembly incorporating bi-facial photovoltaic material, in accordance with an embodiment of the present invention.

### DETAILED DESCRIPTION OF THE INVENTION

Techniques are disclosed for encapsulating a photovoltaic concentrator. The integrity of the encapsulation ensures that a continuous seal is maintained around material interfaces including, for example, at the ends of the lens cell assemblies where there can be a complex three dimensional geometry and electrical leads from photovoltaic material within the lens assembly.

General Overview

The techniques provided herein allow for protection of the photovoltaic material of a lens assembly from the environment, and further allow for an electrical interconnection that provides for increased mechanical and electrical protection of the photovoltaic and electrical interconnections between lens cell assemblies. In addition, the techniques provide a method of leading the electrical contacts from the photovoltaic material within the lens cell assembly such that there is a positive seal provided by the lens encapsulating material.

One particular embodiment includes a passage within the lens itself, which serves as a conduit for the electrical leads from the photovoltaic material. In one such embodiment, the passage is formed at the end of the lens and mates to an opening in a first structural member that is fused to the lens. The first structural member serves to support a series of lens cell assemblies, which can be joined together side-by-side, to make up a solar photovoltaic module.

The first structural member, in turn, provides a wall of a busway normal to the long axis of the lens cell assemblies. After individual lens cell assemblies are electrically interconnected, a second structural member can be fused to the first structural member to form a completely enclosed busway. By having the electrical leads route through a passage or tunnel within the lens itself, an encapsulating film can be fused completely to the substrate lens without any penetration by the electrical leads. The ability to completely wrap and seal the encapsulating film over the lens in combination with the totally enclosed busway allows for a completely secure and highly manufacturable seal over the photovoltaic material.

The encapsulating film can be any durable film. In some embodiments, the film is a clear film (e.g., acrylic). Alternatively, the film can be opaque film with a reflective surface on the lens side (e.g., aluminized PET or mirror film). Opaque films can further be protected from the environment by laminating their outside surface with, for instance, fluoropolymer films.

In some embodiments, a backing strip may be incorporated between the bottom of the photovoltaic material and the encapsulating film. The backing strip serves several functions, including providing mechanical integrity and allowing the encapsulating film to conform to the geometry of the lens. In such a case, the lens geometry can be modified to take into account the presence of this backing strip, so as to provide a complete seal of the assembly with the encapsulating film.

In addition, a raised section at the end of the lens itself, substantially matching the geometry of the backing strip, can be formed between the passage in the lens and the end of the lens, to provide a uniform profile. This uniform profile further facilitates the encapsulating film to completely cover and seal around the lens and the photovoltaic material by extending the film over the raised portion of the lens, as well as the backing strip and/or photovoltaic material. Note, however, that such a uniform profile is not necessary. Factors such as the strength and tear-resistance of the film can be considered when determining the appropriate profile. In general, lower strength films perform better with a uniform profile, while stronger films can better withstand the demands of a non-uniform profile.

Concentrator Lens Cell

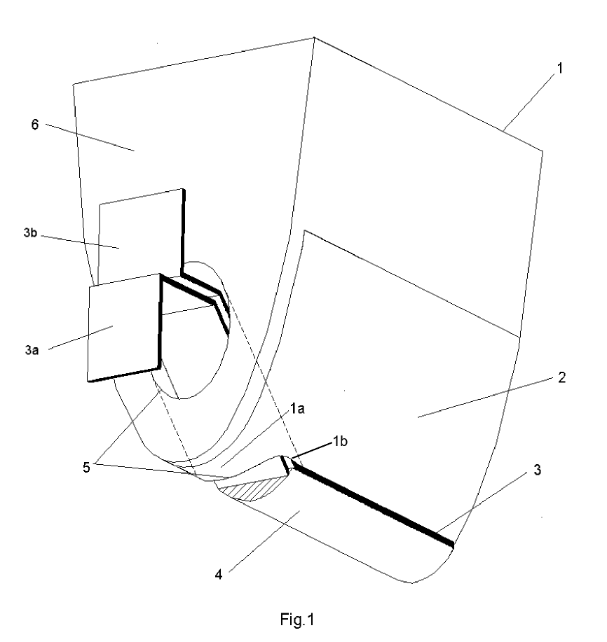

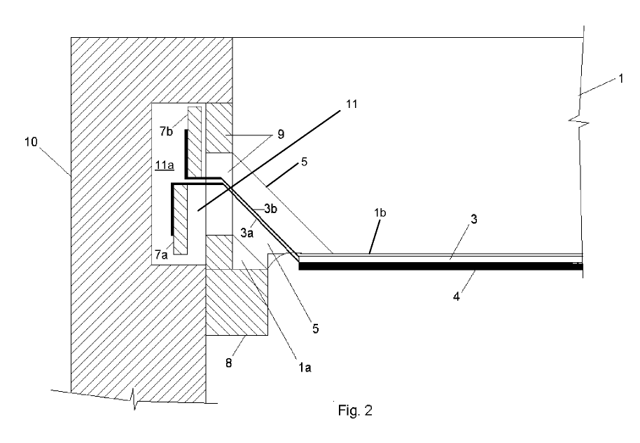

Referring to the drawings, FIG. 1 and FIG. 2 illustrate a concentrator lens cell assembly configured in accordance with an embodiment of the present invention, including a concentrating lens 1, a backing strip 4 to the photovoltaic material 3 at the target of the concentrating lens 1, and a film 2 that encapsulates the assembly. In addition, a passage 5 is provided in the concentrating lens 1 for the electrical contacts 3a, 3b leading off the photovoltaic material 3 that allow for a complete electrical circuit. These electrical contacts 3a, 3b may also provide a means of extracting electrical energy from the photovoltaic material 3.

As can be seen, the passage 5 in this example embodiment is provided from side 6 of lens 1 to the lower portion 1b of lens 1. The passage 5 is effectively a fully enclosed tunnel through at least a portion of the lens 1. In this sense, the passage 5 is internal to the lens, and has a first opening at one end of the passage 5 and another opening at the other end of the passage 5. A raised portion la at the end of the concentrating lens 1 is also provided, which in this example embodiment approximates the profile/shape of the photovoltaic backing strip 4. Thus, the raised portion la in combination with the backing strip 4 provide a relatively uniform profile across the based of the concentrator lens cell assembly.

Such a lens cell assembly can be incorporated into an array of such assemblies, wherein a number (e.g., tens to hundreds) of lens cell assemblies are joined together by structural members. The total number of lens cell assemblies used in one array will depend on factors such as power and/or structural support requirements. In one such embodiment, and as best shown in FIG. 2, the leads 3a and 3b coming off of each individual lens cell assembly are electrically connected, either in series or in parallel to bus bars 7a and 7b. The bus bars 7a-b provide positive and negative electrical contacts, respectively, and may run the length of the array such that each of the leads 3a and 3b of each lens cell assembly connect to a respective one of the bus bars 7a and 7b. The contact between the leads 3a and 3b and respective bus bars 7a and 7b can be made, for example, with conductive epoxy, solder, mechanical fasteners (e.g., nut-and-bolt arrangement), or other suitable mechanism.

With further reference to FIG. 2, many of the same elements discussed with respect to FIG. 1 can be seen in section view. In addition, the passage 5 in the concentrating lens 1 mates to an opening in a first structural member 9. The concentrating lens 1 can be fused, bonded, or otherwise coupled to both the first structural member 9 and a second structural member 10. The second structural member 10 provides structural support for a plurality of concentrator lens cell assemblies that make up a photovoltaic array module section. As can be seen in this example embodiment, the combined structural members 9 and 10 are generally oriented normal to the long axis of the concentrating lens 1.

As can be further seen with reference to FIG. 2, an opening 11 is formed by the joining of the two structural members 9 and 10. This opening 11, with its axis generally normal to the long axis of the concentrating lenses, provides a chamber or ‘busway’ 11a for the electrical connection of the photovoltaic leads 3a and 3b to the positive and negative bus bars 7a and 7b. In this particular example embodiment, a third structural element 8 is fused to structural members 9 and 10 as shown in side-view, and is positioned under the concentrating lens 1 to provide additional mechanical support to the concentrating lens assembly. The upper surface of this third structural member 8 may be shaped to coincide with the shape of the raised portion 1a of the concentrating lens 1 to provide a relatively smooth transition from the third structure member 8 to the concentrating lens 1.

In one such example embodiment, the shape of the raised end 1a of the concentrating lens 1 may approximate the shape of the photovoltaic backing strip 4. Alternatively, the raised end 1a of the concentrating lens 1 may approximate the shape of the photovoltaic material 3. Referring to FIG. 1, this congruence in shape (or profile uniformity) facilitates the encapsulating film 2 to maintain a relatively consistent and uniform form wrapped around the lens cell assembly. Moreover, by extending the encapsulating film 2 over and fusing that film 2 to the raised end 1a of the lens 1, a smooth, unbroken coherent seal is formed over the assembly to provide complete isolation from the environment external to the assembly.

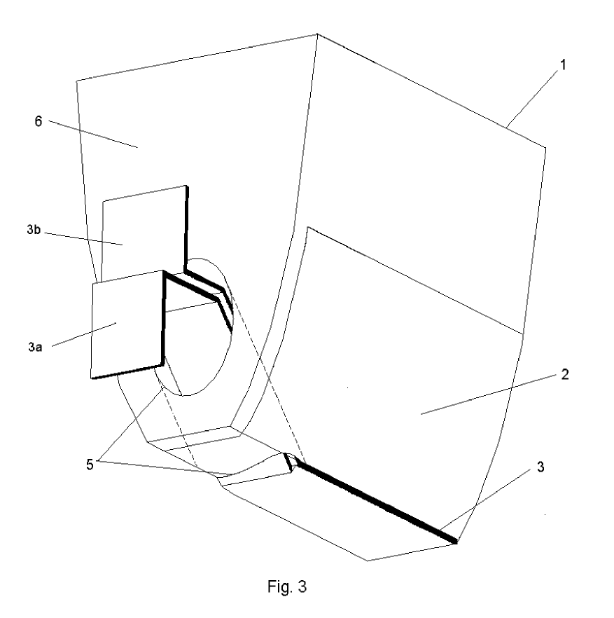

In addition to the embodiment illustrated in FIG. 1 that employs a backing strip 4 having a convex outer surface and a photovoltaic material 3 in a horizontal position with respect to the concentrating lens 1, other embodiments will be apparent in light of this disclosure. For example, FIG. 3 illustrates an embodiment with the photovoltaic material 3 in a horizontal position with respect to the concentrating lens 1, but without the backing strip 4. Still other embodiments may employ a backing strip 4 having a relatively flat outer surface and a photovoltaic material 3 in a horizontal position with respect to the concentrating lens 1. In one such case, the elongated outer edges of the flat backing strip are tapered (to soften the transition to which film 2 will be exposed). The previous discussion with respect to the concentrating lens 1, encapsulating film 2, electrical leads 3a and 3b, passage 5, and other features and structure relative to FIGS. 1 and 2 is equally applicable here.

As will be appreciated in light of this disclosure, a benefit of using a backing strip 4 that is curved (as best shown in FIG. 1) on the outer side that engages with film 2 is that such curvature provides a general continuity to the curve of the encapsulating film 2 that can be used to wrap all or a portion of the outer surface of the concentrating lens 1. This may be important in some applications, for instance, to eliminate or otherwise reduce distorting optics of the concentrating lens 1. Such a convex profile may also assist in holding the backing strip 4 and the photovoltaic material 3 relatively closely to the concentrating lens 1, and in securing the photovoltaic strip 3 so that it remains at the indicated location.

Another function of the backing strip 4 may be to provide a means of thermal conductivity to remove heat from the photovoltaic material 3. Accordingly, the backing strip 4 may be, for instance, a metallic material such as copper (e.g., 401 Watts/m-k) or aluminum (e.g., 237 Watts/m-k), both with relatively high thermal conductivity. In general, any metallic material with a suitable thermal conductivity (e.g., over 50 Watts/m-K, depending on the application) can be used. By being in relative contact or close proximity to the photovoltaic material 3, the backing strip 4 may be able to draw unwanted heat away from the photovoltaic material 3 that may have a deleterious effect on its performance. In addition, because its bottom surface may be curved/convex, it may afford additional area to transfer heat to the surrounding air. Moreover, the assembly of the concentrating lens 1 and the backing strip 4 may form a shape conducive to promoting air turbulence and enhancing convective film heat transfer coefficients, further dissipating unwanted heat.

Yet another feature of the backing strip 4 may be to serve as an electrical conductor for the positive (bottom) side of the photovoltaic material 3. In the example embodiments of FIGS. 1 and 2, the metallic back of the photovoltaic material 3 may be electrically connected at one or more locations to a metallic backing strip 4 by an electrically conductive adhesive, such as silver epoxy. In other embodiments, other electrically conductive materials may be used or the electrical contact may depend on physical contact between the materials. Furthermore, another feature of the backing strip 4 may be to provide support for an electrical inter-connection at the end the lens assembly, for example, by extending at least slightly beyond one or both ends of the concentrating lens 1.

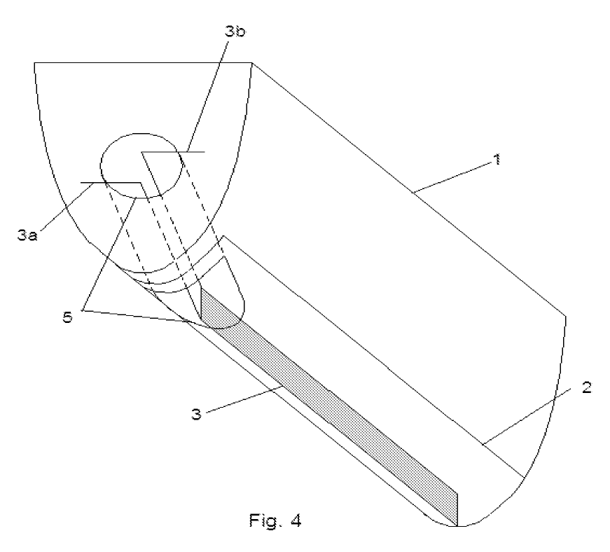

FIG. 4 illustrates another embodiment with the photovoltaic material 3 in a vertical position with respect to the concentrating lens 1. Such an embodiment may be appropriate, for example, when the concentrator lens cell assembly design incorporates a bi-facial photovoltaic material 3 in order to generate electrical energy using both sides of the photovoltaic cell material. In the example embodiment depicted in FIG. 4, electrical leads 3a and 3b are in the form of wires electrically attached to the edges of the bi-facial photovoltaic material 3 and pass through the passage 5 (as well as through the hole in the first structural member 9 and into the busway 11a, as best shown in FIG. 2). The film 2 may encapsulate the concentrator lens cell assembly partially or completely, as described herein.

The electrical leads 3a and 3b and bus bars 7a and 7b can be implemented, for example, with any suitable conductor materials (e.g., aluminum, copper, or steel). The physical form of the electrical leads 3a and 3b and bus bars 7a and 7b can be, for example, insulated wire having insulation removed at points where electrical contact is made (e.g., such as at the point where leads 3a-b contact the photovoltaic material as well as the points where leads 3a-b contact bars 7a-b). Alternatively, the electrical leads 3a and 3b and bus bars 7a and 7b can be in the form of rigid or semi-rigid metallic bars (with or without insulation thereon). Alternatively, the electrical leads 3a and 3b and bus bars 7a and 7b can be in the form of foil strips (with or without rigid backing). Any number of suitable electrical contacting schemes can be used here, as will be apparent in light of this disclosure.

The concentrating lens 1 may be made from, for example, transparent polymer resin material, and can have an elongated shape as generally shown in FIGS. 1, 3, and 4, although other suitable materials and/or shapes can be used as will be apparent in light of this disclosure. In a general sense, concentrating lens 1 can be any lens configuration (e.g., including shape, material, geometry, etc) capable of directing light of a given wavelength or range of wavelengths to a given location. The lens 1 material is transparent, in that it can be any material capable of transmitting light sufficient for absorption by the photovoltaic material 3 to generate electrons. In one example case, the material used to implement lens 1 transmits 50% or more of visible light, including all values and increments between 50-100%. Example such materials include acrylic, polycarbonate, polyethylene terepthalate (PET), cellulosic esters, polystyrene, nylons, poly-4-methyl-1-pentene, etc. The lens 1 material may also include polymeric materials that are primarily amorphous (e.g., greater than 50% amorphous content) and which have a glass transition temperature (Tg) of above 50° C. The materials used to make concentrating lens 1 may also be glass. The lens may have any number of suitable geometries. In one specific example configuration, the lens 1 is three-dimensional and has a height of about 5 to 20 mm, an upper width of about 4 to 8 mm, and a bottom width (given that the lens has a taper) of about 1 to 3 mm.

The lens 1 can be manufactured, for instance, using conventional injection molding techniques, wherein the mold is configured to provide passage 5 within the formed lens 1. In this sense, the lens 1 is unitary and integrally formed as a single construction. Other suitable manufacturing techniques can be used as well in forming the lens 1, such as grinding, drilling, pressing, machining, and/or polishing, so as to provide the desired shape and passage 5.

The structural members 8, 9 and 10 can be made from a variety of materials. In one particular embodiment, they are made of polymeric materials similar in composition to the material of the concentrating lenses 1. Alternative materials (e.g., any plastics, fiberglass, metals, composites, etc) will be apparent in light of this disclosure. The type of materials used for structural members 8, 9 and 10 will depend on factors such as desired weight of the assembly and coupling techiques. Fusing or coupling of these parts can be accomplished by a variety of techniques including, for example, joining by adhesives, solvent welding of like materials, ultrasonic welding, thermal welding, or connection using mechanical fasteners. Note that if diverse materials are used for the structural members 8, 9 and 10 (diverse relative to material of lens 1), such that those diverse materials cannot be strongly bonded by chemical based bonding, then a mechanical coupling means can be used.

As can be seen, the strip of photovoltaic material 3 is positioned along the bottom of the concentrating lens 1 so as to receive the concentrated light. Reference to concentrated light may therefore be understood to be light that has entered the lens assembly and is then directed to the photovoltaic strip. The width of the photovoltaic strip may be, for example, 75-120% of the width of the bottom of the lens. In the embodiment shown, the photovoltaic strip has substantially the same width as the bottom of lens 1. As will be appreciated, this width may be selected to optimize the efficiency of the photovoltaic strip when it comes to interaction with light photons and electron generation and production of electricity. As shown, the bottom of the lens 1 may be substantially flat, but need not be.

The photovoltaic material can be implemented with any material that absorbs photons and generates electrons (e.g., via a photovoltaic effect). The photovoltaic material may be, for instance, a thin-film photovoltaic comprising inorganic layers, organic dyes and organic polymers deposited on a supporting substrate. In one specific example embodiment, such a thin film photovoltaic includes an inorganic material such as copper indium gallium di-selenide (CIGS). It may also include amorphous silicon thin-film photovoltaic materials. Mono or polycrystalline silicon photovoltaic materials may also be used. As will be appreciated, the photovoltaic material 3 may be deposited directly on the concentrating lens 1 by methods such as sputtering and/or vacuum deposition, or otherwise fixed in place.

The backing strip 4 may be made, for example, of shaped electrically conductive wire, such as copper or aluminum, but in other embodiments it may be made of synthetic material such as polymeric material or other solid material. The backing strip 4 may provide a number of additional useful functions. For instance, during manufacturing, it may provide a method of further securing the photovoltaic strip 3 to the lens 1. The backing strip 4 and the photovoltaic material 3 may therefore be joined together by a temporary adhesive such as artwork mounting adhesive or other suitable bonding material, and/or by a magnetic field if the backing strip 4 and/or photovoltaic material 3 have magnetic properties.

As previously explained, the film 2 may be used to effectively laminate the assembly together. The film 2 material may be, for example, any material that may be adhered to the lens 1 and serve to locate and position the photovoltaic material 3 (and backing strip 4, if applicable) as previously explained. In some embodiments, the film 2 has a thickness of about 0.050 mm to about 0.250 mm. Example film 2 materials include polymeric material, such as acrylics, polyester, polycarbonates, cellulosics, etc. Furthermore, the film 2 may have a light transmission capability that is, for instance, within ±10% of the light transmission capability of material used in the lens 1 to provide optical coupling. For example, for an acrylic lens 1 that may transmit about 92% of visible light, the film 2 material may transmit about 82.8-100% of visible light, including all values and increments therein. In addition, the refractive index (Ri) of the film 2 may also be within ±10% of the refractive index of the lens material 1. For an acrylic lens material 1 having a refractive index of about 1.49, for example, the refractive index of the film 2 may be about 1.34-1.64, including all values and increments therein. In addition, the film 2 may be selected and applied to the lens 1 such that it provides total internal reflection (TIR). For instance, the film 2 may be applied to the lens 1 and provide an air gap thereby leading to TIR of light. On the other hand, if the film 2 is adhered to the lens 1 and it provides continuity of refractive index, it will not reflect internally. In any of these embodiments, the film 2 can still be used to locate the photovoltaic strip 3 at the bottom of the lens 1. In addition, the film 2 may be configured such that it may provide TIR yet not be transparent to a given observer.

Thus, the film 2 can be any durable film, and may be transparent, or alternatively, opaque with reflective qualities. A specific example of a clear film that can be used is Polymethyl-methacrylate (PMMA) or acrylic, having a thickness of 0.002 to 0.006 inches to 0.1524 mm) thick, such as that manufactured by EVONIK Industries AG or Spartech® PEP. Specific examples of an opaque/reflective film include aluminized PET or a lamination of PMMA-silver-PET, having a thickness in a range similar to that noted for clear films (e.g., 0.0508 to 0.1524 mm), such as a mirror film manufactured by ReflectTech®. Opaque films can further be protected from the environment by laminating their outside surface with fluoropolymer films, such as Dupont™ Tedlar® polyvinyl fluoride (PVF) films.

The film 2 can be adhered to at least a portion of the two curved sides of the concentrating lens 1, or to the entire lens 1. In either case, this may be accomplished by a variety of techniques. For example, the film 2 can be adhered to the lens utilizing a heat source (e.g., hot air or infrared radiation), and improve the efficiency of bonding by utilizing a heat absorbing dye. Alternatively (or in addition to), the film 2 can be adhered to the lens utilizing techniques such as ultrasonic welding or through the use of laser treatment. In addition, a transparent adhesive can be used, such as an acrylic based adhesive which adhesive may be provided as a solvent based formulation. The solvent based adhesive may then adhere the film 2 and the lens 1 together, thereby eliminating any boundary and making the two substantially homogeneous with respect to optical characteristics.

The outer surface of the film 2 may be selected, for example, such that although transparent to an observer, it also provides total internal reflection (TIR) of the light passing through the lens and interacting with the photovoltaic strip 3. Thus, a flexible film material may be adhered to the lens 1 and wrap about the lens (or a portion thereof) and provide TIR. The film 2 may then be applied so that it may encompass the photovoltaic material 3, backing strip 4 and any other componentry making up the assembly, so as to contain and locate those components. As will be appreciated in light of this disclosure, the film 2 may be selectively adhered to the outer surfaces of the lens 1, and need only be adhered a sufficient amount so that it extend about the bottom of the lens 1 to contain the components as noted herein, and to provide isolation from the environment external to the assembly.

In addition, the film 2 used in conjunction with the lens 1 may have certain optical characteristics, such as when using a non-imaging compound parabolic concentrator for the lens 1. This may then allow light incident on the lens 1, at certain oblique angles (angles other than 90 degrees with respect to the upper horizontal surface of the lens 1), to pass through without hitting the photovoltaic material 3. Conversely, certain light traveling in an opposite direction through the lens 1 may be reflected/refracted from the upper surface of the lens 1 at oblique angles. In some embodiments, transparency of film 2 and lens 1 may therefore allow unique visual effects for such building components as skylights, windows, roofing and certain wall configurations, including daylighting (passage of light) and/or offering the appearance of a background color and texture to an observer while concurrently concentrating the light to the photovoltaic material 3 to generate electricity.

In another specific embodiment, the film 2 is adhered to only a portion of the sides of the concentrating lens 1, and a dielectric material (e.g., fluid or gel) is deployed in pockets between the lens 1 and film 2 as described in the previously incorporated U.S. patent application Ser. No. 11/773,866, to provide optical continuity between the concentrating lens 1 and the film 2 in those areas that are not fused together. Such dielectric materials may have molecular weights (MW), for example, of less than or equal to about 15,000. Suitable dielectric materials may be, for instance, any electrically non-conductive material that may be made to flow with applied pressure at temperatures of less than about 50° C. and position itself between the lens 1 and photovoltaic material 3, and if present, backing strip 4. The dielectric material may be, for example, a mineral or paraffin oil, or a low molecular weight hydrocarbon or a grease and/or wax having a molecular weight of less than or equal to about 15,000. It may also include glycerin, but other types of suitable transparent oils, fluids or gels may be used as well, including vegetable oils (oils sourced from plants). The dielectric material may also have refractive index that is equal to or within about +20% of the value of the refractive index of the lens 1 and/or film 2. The dielectric material may also be generally hydrophobic which may be understood as a fluid that is not miscible with water. For example, the dielectric material may include a silicon based fluid, such as a fluid based upon a relatively lower molecular weight polysiloxane (e.g., polydimethylsiloxane or PDMS) having a number average molecular weight of equal to or less than about 5000. In addition, such dielectric materials may provide thermal stability over the temperatures of application (e.g., −50° C. to about 125° C.) and avoid gellation. In addition, the dielectric material may be selected such that it has a relatively low permeability to diffusion of water. Fluids resulting in a water vapor transmission rate (WVTR) of less than or equal to 0.5 g/m²-day at 25° C. and 50% relative humidity may therefore provide desired protection against corrosion of the photovoltaic material 3 by water vapor. In addition, a water barrier coating can be supplied to the film 2 to further reduce water permeability. Such a coating may also be photo-transparent, and may be sourced in polymeric resins such as polyurethanes, acrylics, etc. The dielectric material may be incorporated into a pocket at the bottom of the concentrating lens 1 assembly and may occupy any space where the film 2 is not adhered to the concentrating lens 1. The fluid may also be introduced into such pocket at a positive pressure which may provide improved coating of the components therein. The dielectric material may also provide: (a) optical coupling between the bottom of the concentrating lens 1 and the photovoltaic material 3; (b) lubrication of the surfaces of the lens 1, photovoltaic material 3 and optional backing strip 4 so they may independently expand and contract when subjected to heat; (c) electrical insulation of the electrical conductors from the outside environment; (d) reduced ingress of moisture from the outside environment; and (e) a thin liquid film type coating between the concentrating lens 1 and the photovoltaic material 3.

The foregoing description of the embodiments of the invention has been presented for the purposes of illustration and description. It is not intended to be exhaustive or to limit the invention to the precise form disclosed. Many modifications and variations are possible in light of this disclosure. It is intended that the scope of the invention be limited not by this detailed description, but rather by the claims appended hereto.

What is claimed is:

1. A photovoltaic assembly, comprising:
a concentrating lens having a passage therein for electrical leads;
a photovoltaic material at a target of the concentrating lens and operatively coupled to the electrical leads; and
a film that encapsulates the assembly without any break in the film to accommodate the electrical leads.

2. The assembly of claim 1 further comprising:
a backing strip to the photovoltaic material.

3. The assembly of claim 2 wherein the backing strip has a convex outer shape that the film wraps around.

4. The assembly of claim 2 wherein the concentrating lens has a lower portion where the photovoltaic material is located and a raised portion at one end of the lower portion, the raised end approximating a shape of the photovoltaic material and backing strip.

5. The assembly of claim 1 wherein the assembly is used in an array including a plurality of assemblies.

6. The assembly of claim 5 wherein the electrical leads of each assembly are electrically connected to respective bus bars.

7. The assembly of claim 1 wherein an opening of the passage in the concentrating lens mates to an opening in a structural member coupled to the concentrating lens.

8. The assembly of claim 7 wherein the opening provides access to an enclosed busway that houses negative and positive bus bars to which the electrical leads can be operatively coupled.

9. The assembly of claim 1 wherein the film is a clear film.

10. The assembly of claim 1 wherein the film is an opaque film with a reflective surface on the concentrating lens side.

11. A photovoltaic assembly, comprising:
a concentrating lens having a passage therein for electrical leads, wherein an opening of the passage mates to an opening in a structural member coupled to the concentrating lens;
a photovoltaic material at a target of the concentrating lens and operatively coupled to the electrical leads;
a film that encapsulates the assembly without any break in the film to accommodate the electrical leads;
a backing strip to the photovoltaic material, wherein the backing strip has a convex outer shape that the film wraps around.

12. The assembly of claim 11 wherein the concentrating lens has a lower portion where the photovoltaic material is located and a raised portion at one end of the lower portion, the raised end approximating a shape of the photovoltaic material and backing strip.

13. The assembly of claim 11 wherein the assembly is used in an array including a plurality of assemblies.

14. The assembly of claim 13 wherein the electrical leads of each assembly are electrically connected to respective bus bars.

15. The assembly of claim 11 wherein the opening provides access to an enclosed busway that houses negative and positive bus bars to which the electrical leads can be operatively coupled.

16. The assembly of claim 11 wherein the film is a clear film.

17. The assembly of claim 11 wherein the film is an opaque film with a reflective surface on the concentrating lens side.

18. A photovoltaic assembly, comprising:
a concentrating lens having a passage therein for electrical leads, wherein an opening of the passage mates to an opening in a structural member coupled to the concentrating lens, and the opening provides access to an enclosed busway that houses negative and positive bus bars to which the electrical leads can be operatively coupled;
a photovoltaic material at a target of the concentrating lens and operatively coupled to the electrical leads; and
a film that encapsulates the assembly without any break in the film to accommodate the electrical leads, wherein the film is one of a clear film or an opaque film with a reflective surface on the concentrating lens side;
wherein the assembly is used in an array including a plurality of assemblies, and the electrical leads of each assembly are electrically connected to respective bus bars.

19. The assembly of claim 18 further comprising:
a backing strip to the photovoltaic material, wherein the backing strip has a convex outer shape that the film wraps around.

20. The assembly of claim 18 wherein the concentrating lens has a lower portion where the photovoltaic material is located and a raised portion at one end of the lower portion, the raised end approximating a shape of the photovoltaic material and backing strip.
